(19) United States
(12) Patent Application Publication
(10) Pub. No.: US 2013/0018489 A1
(43) Pub. Date: Jan. 17, 2013

(54) COMBINED FORCE AND PROXIMITY SENSING

(71) Applicants: Martin Paul GRUNTHANER, Mountain View, CA (US); Fletcher R. ROTHKOPF, Los Altos, CA (US); Christopher Tenzin MULLENS, San Francisco, CA (US); Steven Porter HOTELLING, Los Gatos, CA (US); Sean Erik O'CONNOR, Palo Alto, CA (US)

(72) Inventors: Martin Paul GRUNTHANER, Mountain View, CA (US); Fletcher R. ROTHKOPF, Los Altos, CA (US); Christopher Tenzin MULLENS, San Francisco, CA (US); Steven Porter HOTELLING, Los Gatos, CA (US); Sean Erik O'CONNOR, Palo Alto, CA (US)

(21) Appl. No.: 13/183,371

(22) Filed: Jul. 14, 2011

(51) Int. Cl. G05B 21/02; G01R 27/26

(52) U.S. Cl. 700/73; 324/686

(57) ABSTRACT

Combined force and proximity sensing is disclosed. One or more sensors can concurrently sense a force applied by an object on a device surface and a proximity of the object to the surface. In an example, a single sensor can sense both force and proximity via a resistance change and a capacitance change, respectively, at the sensor. In another example, multiple sensors can be used, where one sensor can sense force via either a resistance change or a capacitance change and another sensor can sense proximity via a capacitance change.

### FIELD

This relates generally to input sensing and more particularly to input sensing using combined force and proximity sensing.

### BACKGROUND

One of the most common input mechanisms in a consumer product device is a button, which when contacted by a user causes the device to change a state associated with the button. Pressing or selecting the button can activate or deactivate some state of the device and cause an associated action to be performed. Not pressing or selecting the button can leave the device in its current state with no associated action being performed. The traditional button has been the mechanical push button, such as keys, knobs, and the like, that can be activated or deactivated by a force applied to the button that is detected by a mechanical switch, force sensor, or the like. While accidental activations do happen, they are infrequent because of the amount of force required. With the advent of touch technology, the virtual button, such as a graphical user interface input area displayed on a touch sensitive display, has become very popular and can be activated or deactivated by a touch at the button that is detected by a proximity sensor. However, because a virtual button requires little or no force to activate, accidental activations are more frequent, causing unintended and sometimes damaging action to be performed on the device.

Therefore, in order for a button to operate properly, it is important that the button's input to the device be interpreted correctly to indicate that the button has been intentionally activated.

### SUMMARY

This relates to combined force and proximity sensing, in which one or more sensors can concurrently sense a force applied by an object on a surface and a proximity of the object to the surface. In an example, a single sensor can sense both force and proximity via a resistance change and a capacitance change, respectively, at the sensor. In another example, one sensor can sense force via either a resistance change or a capacitance change and another sensor can sense proximity via a capacitance change. Combined force and proximity sensing can be used with a device's input mechanism, e.g., a virtual button. By sensing both force and proximity of an object at the input mechanism before the device changes state and performs an associated action, combined force and proximity sensing can advantageously increase detection of intended contact on a device and decrease detection of accidental contact on the device.

### BRIEF DESCRIPTION OF THE DRAWINGS

FIG. 1 illustrates an exemplary sensing device having a combined force and proximity sensor according to various embodiments.

FIGS. 2A through 2E illustrate an exemplary force sensor according to various embodiments.

FIG. 3 illustrates an exemplary sensing device having a force sensor and a proximity sensor according to various embodiments.

FIG. 4 illustrates another exemplary sensing device having a force sensor and a proximity sensor according to various embodiments.

FIGS. 5A through 5D illustrate an exemplary proximity sensor according to various embodiments.

FIGS. 5E through 5H illustrate another exemplary force sensor according to various embodiments.

FIG. 6 illustrates another exemplary sensing device having a combined force and proximity sensor according to various embodiments.

FIG. 7 illustrates an exemplary sensing device having a flexible circuit and a rigid conductive member to provide a proximity sensor and a force sensor according to various embodiments.

FIG. 8 illustrates an exemplary sensing device having a flexible circuit and a compliant conductive member to provide a proximity sensor and a force sensor according to various embodiments.

FIG. 9 illustrates an exemplary sensing device having a sealing element applied thereto according to various embodiments.

FIG. 10 illustrates an exemplary sensing device having a flexible circuit and a capacitive electrode to provide a proximity sensor and a force sensor according to various embodiments.

FIG. 11 illustrates another exemplary sensing device having a flexible circuit and a capacitive electrode to provide a proximity sensor and a force sensor according to various embodiments.

FIG. 12 illustrates an exemplary sensing device having a double flexible circuit to provide a proximity sensor and a force sensor according to various embodiments.

FIG. 13 illustrates an exemplary display device having multiple force sensors disposed around the device perimeter according to various embodiments.

FIG. 14 illustrates an exemplary sensing device having a dimple in a surface and capacitive electrodes proximate thereto to provide a combined force and proximity sensor according to various embodiments.

FIG. 15 illustrates an exemplary sensing device having multiple force sensors with a first sensor configured to sense force and the other sensors configured to sense noise.

FIG. 16 illustrates an exemplary method for sensing combined force and proximity at a device according to various embodiments.

FIG. 17 illustrates an exemplary computing system for sensing combined force and proximity according to various embodiments.

FIG. 18 illustrates an exemplary mobile telephone having combined force and proximity sensing capabilities according to various embodiments.

FIG. 19 illustrates an exemplary digital media player having combined force and proximity sensing capabilities according to various embodiments.

FIG. 20 illustrates an exemplary personal computer having combined force and proximity sensing capabilities according to various embodiments.

### DETAILED DESCRIPTION

In the following description of example embodiments, reference is made to the accompanying drawings in which it is shown by way of illustration specific embodiments that can be practiced. It is to be understood that other embodiments can be used and structural changes can be made without departing from the scope of the various embodiments.

This relates to combined force and proximity sensing, in which one or more sensors can concurrently sense a force applied by an object on a surface and a proximity of the object to the surface. In some embodiments, a single sensor can sense both force and proximity together via a resistance change and a capacitance change, respectively, at the sensor. In some embodiments, multiple sensors can be used concurrently, where one sensor can sense force via either a resistance change or a capacitance change and another sensor can sense proximity via a capacitance change. This can advantageously prevent a device from changing state and performing an associated action unless both force and proximity of an object have been concurrently detected.

Although some embodiments are described herein in terms of resistive and capacitive sensors to detect force and proximity, it is to be understood that other types of sensors can be used according to various embodiments.

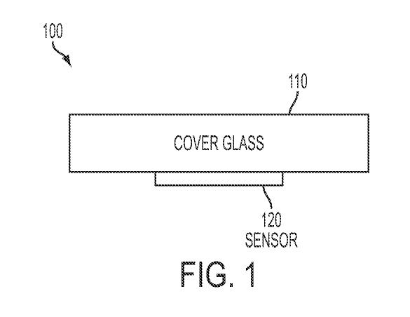

FIG. 1 illustrates an exemplary sensing device having a combined force and proximity sensor according to various embodiments. In the example of FIG. 1, sensing device 100 can include a cover glass 110 having a touchable surface that an object can hover over, touch, or press on. The device 100 can also include combined force and proximity sensor 120 disposed on a surface of the cover glass 110 opposite the touchable surface, although in other embodiments the sensor 120 may be supported on another substrate adjacent to the cover glass. The sensor 120 can sense the force applied by an object pushing on the touchable surface and the proximity of the object to the surface. In some embodiments, the sensor 120 can be a hybrid resistive-capacitive sensor, such as a force sensitive resistor. In some embodiments, the cover 110 can be glass, plastic, or any suitable material capable of providing a substantially rigid substrate having a touchable surface.

The sensor 120 can be coupled to a voltage supply (not shown) to drive the sensor to detect the force applied, the object proximity, or both. The sensor 120 can output a sensing signal indicative of the detected force or proximity to a sensing circuit (not shown) for processing.

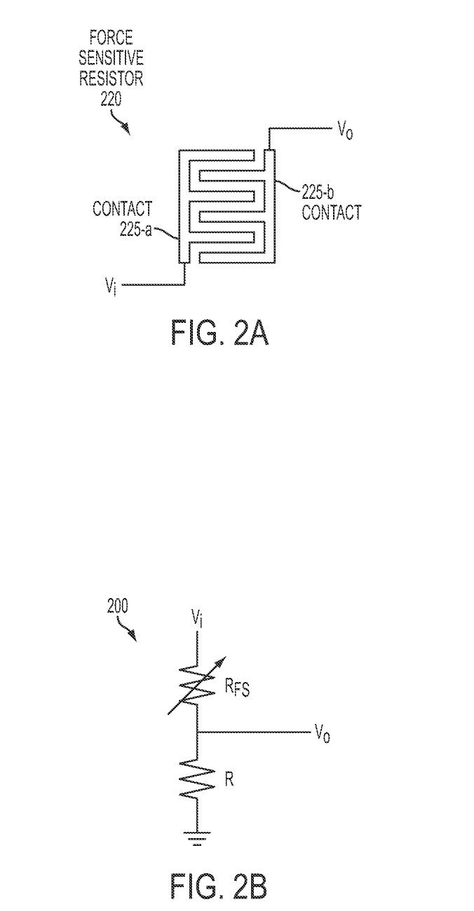

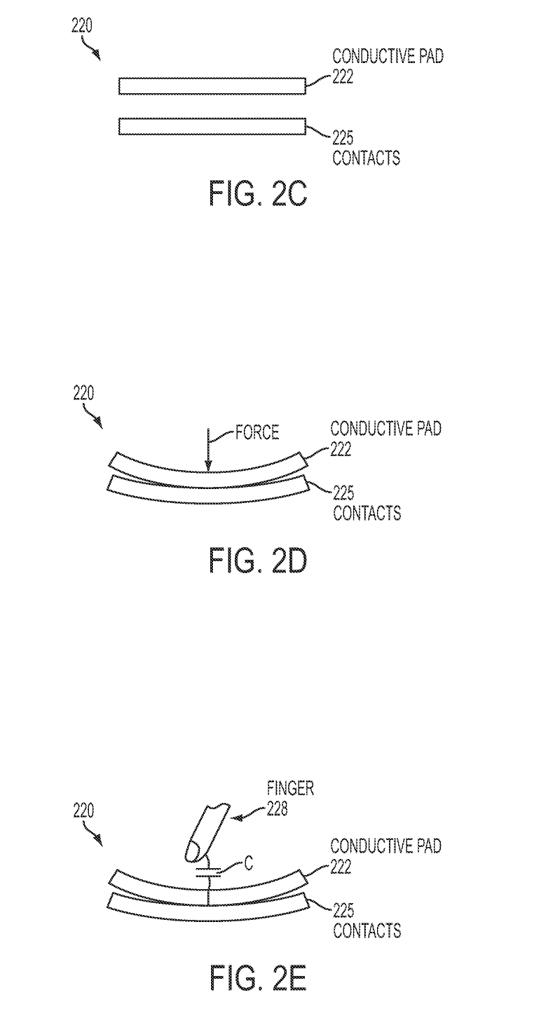

FIGS. 2A through 2E illustrate an exemplary force sensor that can be used in the sensing device of FIG. 1 to detect force and proximity of an object. FIG. 2A illustrates a top view of the force sensor, which in this case can be a force sensitive resistor. In the example of FIG. 2A, force sensitive resistor 220 can include two interleaved contacts 225-a, 225-b positioned closely together, but not touching, while at rest, although it should be understood that other contact configurations can also be employed. Contact 225-a can be coupled to a voltage supply to receive voltage Vi. Contact 225-b can be coupled to a voltage output to transmit voltage Vo. As shown in FIG. 2C, the resistor 220 can also include conductive pad 222 covering, but not touching the contacts 225, while at rest. With no force applied, i.e., while at rest, the resistor 220 can look like an infinite resistor (an open circuit). The resistor 220 can be positioned under the cover glass 110 at a location where force is to be applied.

When force is applied to the cover glass 110, as in FIG. 2D, the cover glass can bow, causing the conductive pad 222 to similarly bow and push against the contacts 225. The conductive pad 222 can form a conductive bridge between the contacts 225-a, 225-b to allow current supplied by voltage Vi to flow through the resistor 220. As a result, the resistance in the resistor 220 can be reduced. As the force being applied increases, the resistance can correspondingly decrease. Thus, when a sensing circuit of the sensing device 100 detects a drop in resistance of the resistor 220, the drop can be interpreted as a force being applied to the cover glass 110. A baseline resistance can be established when the resistor 220 is at rest (i.e., the contacts are in an equilibrium state) and can be compared to the resistance when force is applied in order to determine the drop. In the example of FIG. 2B, voltage divider 200 can be used to detect the resistance drop of the resistor 220. The divider 200 can include the resistor 220 (illustrated as Rfs) having voltage input Vi and coupled to another resistor (illustrated as R). The divider 200 can output voltage Vo as an indication of the resistance drop.

Concurrently therewith, a proximity of the object applying the force can be detected. The resistor 220 can act as a self capacitive sensor with a capacitance to ground. As shown in FIG. 2E, when the object, e.g., finger 228, is proximate to the cover glass 110, the resistor 220 can capacitively couple to the object, causing charge to be shunted from the resistor to the object. As a result, the capacitance at the resistor 220 can be reduced. As the object gets closer to the cover glass 110, the amount of shunted charge can continue to increase and the capacitance can continue to decrease. Thus, when a sensing circuit of the sensing device 100 detects a drop in capacitance at the resistor 220, the drop can be interpreted as an object being proximate to the cover glass 110. A baseline capacitance can be established when there are no objects proximate to the resistor 220 and can be compared to the capacitance when the object is proximate in order to determine the drop. In some embodiments, an additional conductive element can be positioned proximate to the resistor 220 to form a mutual capacitive sensor with the resistor. The capacitance drop between the two can then be detected to determine object proximity.

In response to the object force and proximity, an action can be performed by a computing device operating the sensing device. In some embodiments, an action can be triggered just by the indication of force and proximity. In some embodiments, the triggered action can be a function of how much force is applied to the sensing device, i.e., based on the magnitudes of the resistance drop and the capacitance drop. For example, a light force can trigger one action, while a heavier force can trigger a different action. In some embodiments, the triggered action can be a function of the sequence of presses on the sensing device. For example, two presses in rapid succession can trigger one action, while three presses can trigger another action. Other types of applied forces are also possible according to the requirements of the sensing device.

In some embodiments, the resistor 220 can have two sets of traces, one set to transmit resistance data to the sensing circuit and another set to transmit capacitance data to the circuit. In some embodiments, the resistor 220 can have one set of traces and a switching mechanism to switch between a resistance mode for transmitting resistance data along the traces to the sensing circuit and a capacitance mode for transmitting capacitance data along the traces to the circuit. These trace configurations can be used with other sensing devices described herein that have a combined force and proximity sensor. In some embodiments, the sensing circuit can be a processor.

The sensor 120 can be attached to the cover glass 110 in any number of ways. For example, the sensor 120 can be glued, sputtered, printed, etched, chemically deposited, or otherwise attached to the cover glass 110. In other embodiments, the sensor 120 can be attached to a different substrate in a similar manner. The traces from the sensor 120 to the sensing circuit can similarly be attached to the cover glass 110 and other device components in route to the sensing circuit.

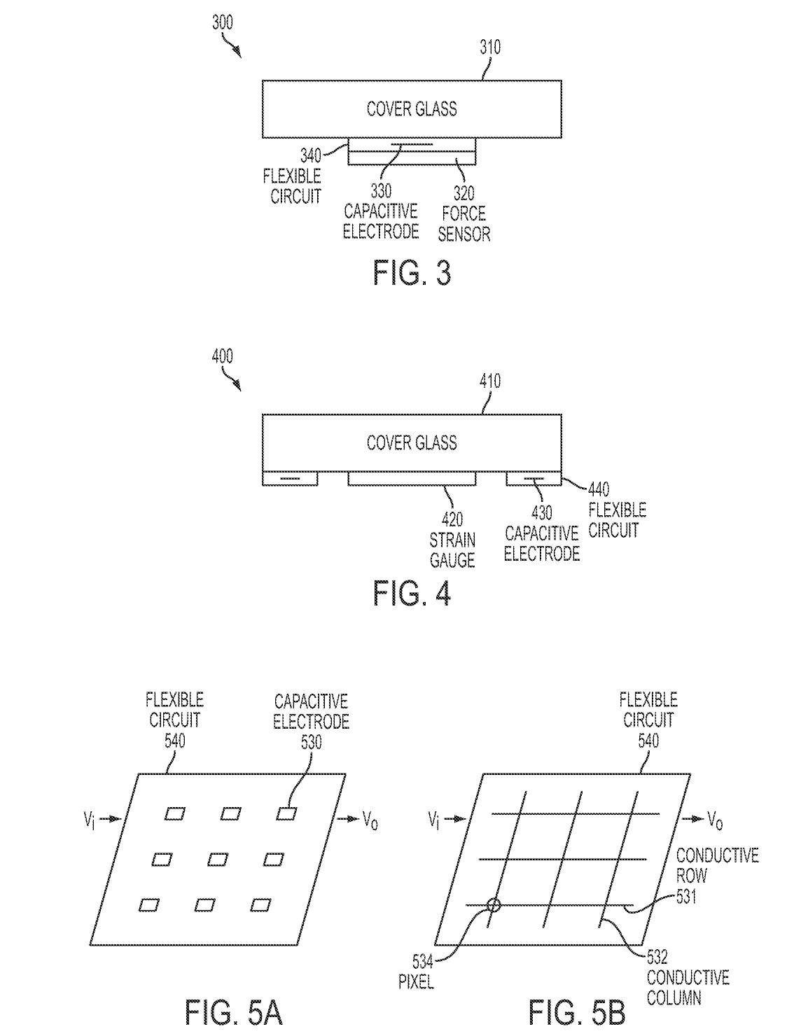

FIG. 3 illustrates an exemplary sensing device having a force sensor and a proximity sensor according to various embodiments. In the example of FIG. 3, sensing device 300 can include cover glass 310, like that of FIG. 1. The device 300 can also include flexible circuit 340 having one or more capacitive electrodes 330 embedded therein and disposed on a surface of the cover glass 310 opposite the touchable surface. Although in other embodiments, the flexible circuit 340 can be supported on another substrate adjacent to the cover glass 310. The capacitive electrode 330 in the flexible circuit 340 can act as a proximity sensor. The device 300 can also include force sensitive resistor 320 stacked onto the flexible circuit 340 to act as a force sensor. The flexible circuit 340 can be any flexible substrate suitable for having one or more elements disposed on or embedded in the circuit for sensing and transmitting data to a sensing circuit.

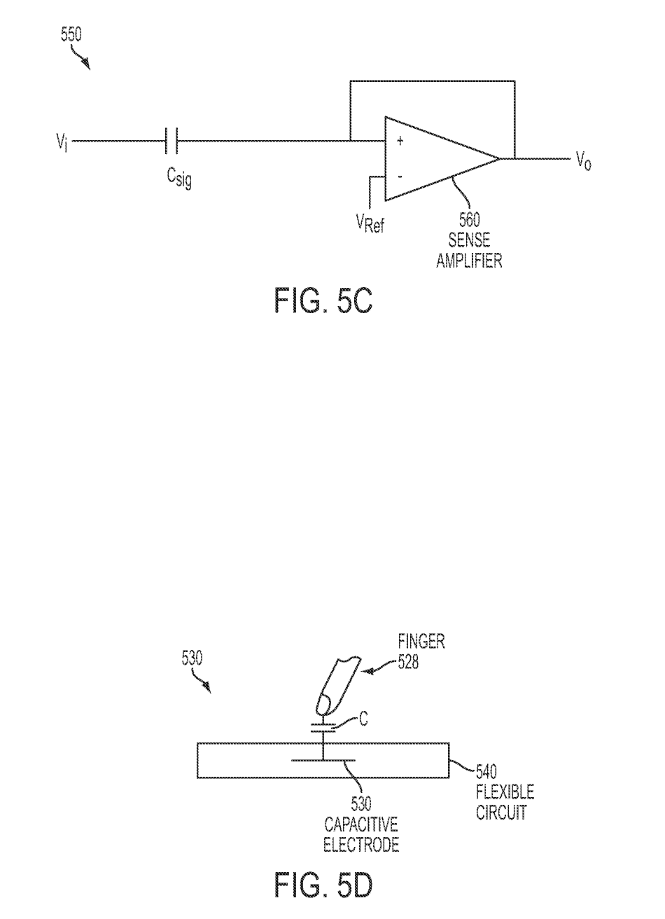

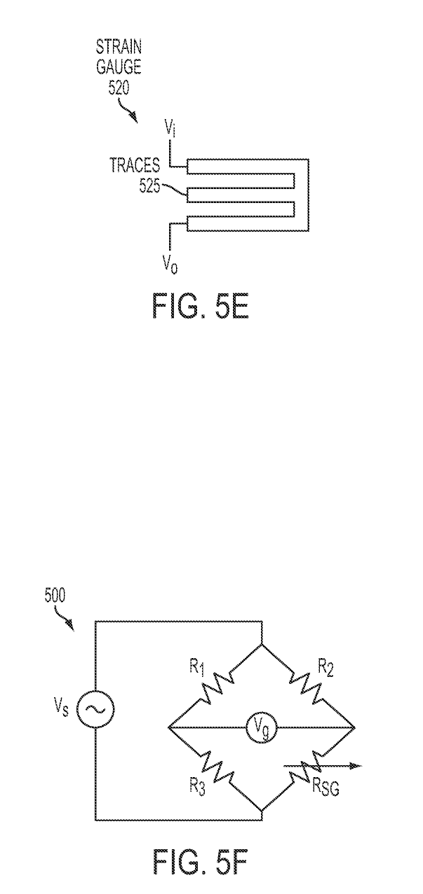

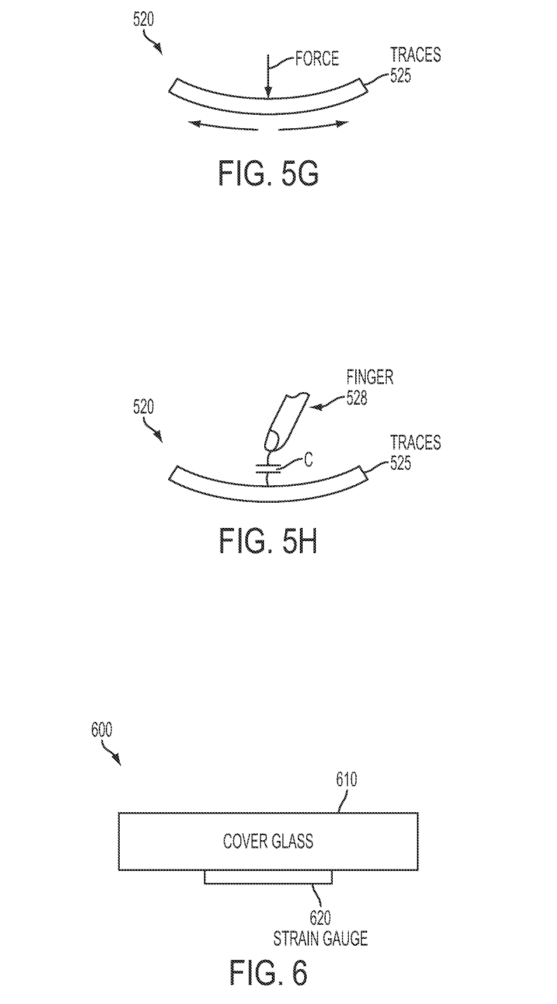

FIGS. 5A through 5D illustrate an exemplary proximity sensor that can be used in the sensing device of FIG. 3 to detect proximity of an object. FIG. 5A illustrates a top view of proximity sensors, which in this case can be self capacitive. In the example of FIG. 5A, flexible circuit 540 can have capacitive electrodes 520 embedded therein. The capacitive electrodes 520 can be based on self capacitance. In a self capacitive sensor, the self capacitance of the electrodes 520 can be measured relative to some reference, e.g., ground. The electrodes 520 can be spatially separated elements, where each electrode can define a proximity sensor. The electrodes 520 can be coupled to a driving circuit (not shown) to drive the electrodes to detect the object proximity and to a sensing circuit (not shown) to process signals indicative of the proximity.

When the object is proximate to the cover glass 310, as in FIG. 5D, the electrode 530 can capacitively couple to the object, e.g., finger 528, causing charge to be shunted from the electrode to the object. This can reduce the capacitance at the electrode. As the object gets closer to the cover glass 310, the amount of shunted charge can continue to increase and the capacitance to correspondingly decrease. Thus, when a sensing circuit of the sensing device 400 detects a drop in capacitance of the electrode 530, the drop can be interpreted as an object being proximate to the cover glass 310. A baseline capacitance can be established when there are no objects proximate to the electrode 530 and can be compared to the capacitance when the object is proximate in order to determine the drop. In the example of FIG. 5C, circuit 550 can be used to detect the capacitance drop at the electrode 530. The circuit 550 can include a drive circuit (not shown) to provide drive voltage Vi to the capacitive electrode 530 (illustrated as Csig). The circuit 550 can also include sense amplifier 560 to receive and process the capacitance signal indicative of the object proximity and to output voltage Vo.

FIG. 5B illustrates a top view of alternative proximity sensors, which in this case can be mutually capacitive. In the example of FIG. 5B, flexible circuit 540 can have conductive rows 531 and columns 532 forming spatially separated drive and sense lines, respectively. Here, the conductive rows 531 and columns 532 can cross each other to form pixels 534 at the cross locations, where each pixel can define a proximity sensor. Other configurations of the drive and sense lines are also possible, such as side by side. The conductive rows 531 can be coupled to a driving circuit (not shown) to drive the rows and the conductive columns 532 to a sensing circuit (not shown) to process signals indicative of the object proximity. The proximity sensors of FIG. 5B can detect the object proximity in a similar manner as the proximity sensors of FIG. 5A.

Referring again to FIG. 3, the resistor 320 can detect force applied by an object to the cover glass 310 in the same manner as described previously in FIG. 2. Concurrently therewith, the electrode 330 can detect the proximity of the object applying force to the cover glass 310 via a capacitance change, as described in FIGS. 5A through 5D.

In some embodiments, the electrode 330 and the resistor 320 can have separate sets of traces to the sensing circuit. In some embodiments, the separate sets of traces can be input to a switching mechanism, which can then connect to the sensing circuit through one set of traces and can switch between the electrode and resistor input traces. These trace configurations can be used with other sensing devices described herein that have separate force and proximity sensors.

In an alternate embodiment, the sensing device 300 can include a spring material stacked onto the resistor 320 to exert a force against the resistor proportional to the bowing of the resistor, measured via the drop in resistance. The spring material can help the resistor 320 return to rest.

FIG. 4 illustrates another exemplary sensing device having a force sensor and a proximity sensor according to various embodiments. In the example of FIG. 4, sensing device 400 can include cover glass 410, like that of FIG. 1. The device 400 can also include strain gauge 420 disposed on a surface of the cover glass 410 opposite the touchable surface to act as a force sensor, although in other embodiments the strain gauge 420 can be supported on another substrate adjacent to the cover glass 410. The gauge 420 can be positioned under a cover glass location where force will be applied. The device 400 can also include flexible circuit 440, having capacitive electrode 430 embedded therein, disposed on the surface of the cover glass 410 opposite the touchable surface. The capacitive electrode 430 can act as a proximity sensor. The flexible circuit 440 can be positioned side by side with the gauge 420, or in other orientations.

FIGS. 5E through 5H illustrate an exemplary force sensor that can be used in the sensing device of FIG. 4 to detect force applied by an object. FIG. 5E illustrates a top view of the force sensor, which in this case can be a strain gauge. In the example of FIG. 5E, strain gauge 520 can include traces 525 positioned closely together, but not touching, while at rest. The gauge 520 can be coupled to a voltage supply to receive voltage Vi and to a voltage output to transmit voltage Vo. When force is applied to the cover glass 410 under which the gauge 520 is disposed, as in FIG. 5G, the cover glass can bow, causing the traces 525 to stretch and become longer and narrower, thereby increasing the gauge resistance. As the force being applied increases, the gauge resistance can correspondingly increase. Thus, when a sensing circuit of the sensing device 400 detects a rise in resistance of the gauge 520, the rise can be interpreted as a force being applied to the cover glass 410. A baseline resistance can be established when the gauge 520 is at rest and can be compared to the resistance when force is applied in order to determine the rise. In the example of FIG. 5F, bridge 500 can be used to detect the resistance increase of the gauge 520. The bridge 500 can include the gauge 520 (illustrated as Rsg) and three other resistors (illustrated as R1, R2, R3). The bridge 500 can also include a meter to detect the current flow provided by Vg to help determine the resistance increase in the gauge 520.

Referring again to FIG. 4, concurrently, the electrode 430 in the flexible circuit 440 can detect the proximity of the object applying force to the cover glass 410 via a capacitance change in the same manner as the electrode of FIG. 3, and the gauge 420 can detect the force applied via a resistance change, as described in FIGS. 5E through 5G.

FIG. 6 illustrates another exemplary sensing device having a combined force and proximity sensor according to various embodiments. The sensing device of FIG. 6 can be the same as the sensing device of FIG. 1, except strain gauge 620 in FIG. 6 can replace force sensor 120 in FIG. 1. The strain gauge 620 can detect force applied to cover glass 610 in the same manner as in FIG. 5. Concurrently therewith, the gauge 620 can detect the proximity of the object, e.g., finger 528, applying force to the cover glass 610, as shown in FIG. 5H. That is, when the object is proximate to the cover glass 610, the gauge 620 can capacitively couple to the object, causing charge to be shunted from the gauge to the object, thereby reducing the gauge capacitance. As the object gets closer to the cover glass 610, the amount of shunted charge can continue to increase and the gauge capacitance to correspondingly decrease. Thus, when a sensing circuit of the sensing device 600 detects a drop in capacitance of the gauge 620, the drop can be interpreted as an object being proximate to the cover glass 610. A baseline capacitance can be established when there are no objects proximate to the gauge 620 and can be compared to the capacitance when the object is proximate in order to determine the drop.

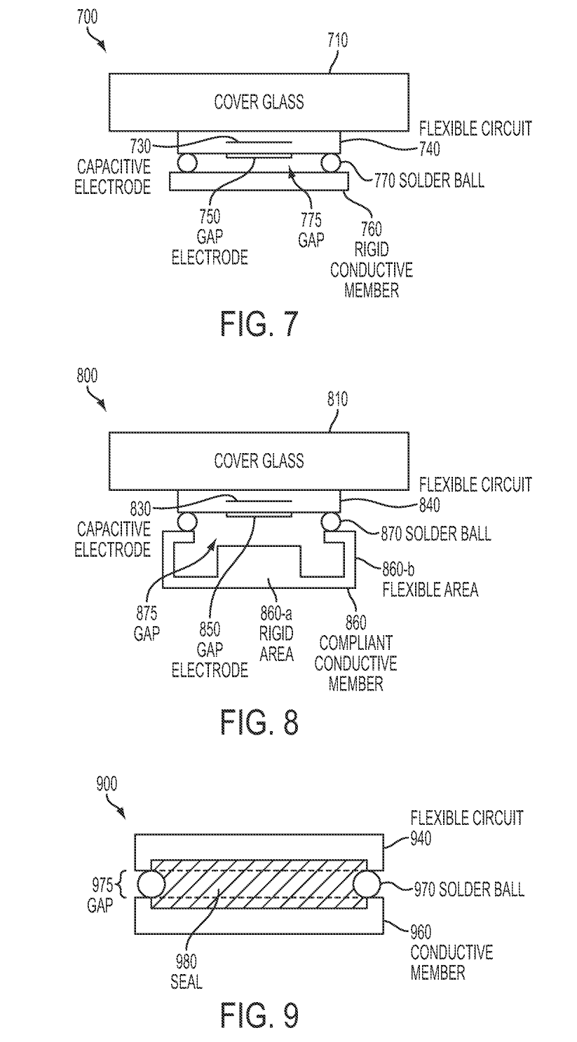

FIG. 7 illustrates an exemplary sensing device having a flexible circuit and a substantially rigid conductive member to provide a force sensor and a proximity sensor according to various embodiments. In the example of FIG. 7, sensing device 700 can include cover glass 710, like that of FIG. 1. The device 700 can also include flexible circuit 740, having capacitive electrode 730 embedded therein, disposed on a surface of the cover glass 710 opposite the touchable surface of the cover glass. The capacitive electrode 730 can act as a proximity sensor. The device 700 can also include gap electrode 750 disposed on a surface of the flexible circuit 740 opposite the surface proximate to the cover glass 710. The gap electrode 750 can be a capacitive electrode and can form the first element of a force sensor. The device 700 can include a substantially rigid conductive member 760 coupled to the flexible circuit 740 via solder balls 770 to form the second element of the force sensor. The member 760 can be metal or any other suitable conductive material. Other spacer elements, rather than the solder balls 770, can be used to couple the member 760 to the circuit 740. The spacer elements can be either rigid or deformable according to the sensing device requirements. Gap 775 can be formed between the member 760 and the circuit 740. In some embodiments, the gap can be filled with air. In some embodiments, the gap can be filled with dielectric material to improve the gain of the force signal.

When force is applied to the cover glass 710, the cover glass can bow, causing the flexible circuit 740 to bow as well to close the gap 775 between the gap electrode 750 and the member 760. This can result in increased capacitance between the electrode 750 and the member 760. As the force being applied increases, the gap electrode-rigid member capacitance can also increase. Thus, when a sensing circuit of the sensing device 700 detects a rise in capacitance between them, the rise can be interpreted as a force being applied to the cover glass 710. A baseline capacitance can be established when the gap is at a maximum between the gap electrode 750 and the rigid member 760 and can be compared to the capacitance when force is applied in order to determine the rise.

Concurrently therewith, the capacitive electrode 730 can detect the proximity of the object applying the force via a capacitance change in the same manner as the electrode of FIG. 3.

FIG. 8 illustrates an exemplary sensing device having a flexible circuit and a compliant conductive member to provide a force sensor and a proximity sensor according to various embodiments. The sensing device 800 of FIG. 8 can be the same as the sensing device 700 of FIG. 7, except compliant conductive member 860 in FIG. 8 can replace rigid conductive member 760 of FIG. 7. In the example of FIG. 8, the compliant conductive member 860 can have rigid area 860-a disposed directly below gap electrode 850 and flexible areas 860-b at the solder balls 870. This configuration can advantageously keep the rigid area 860-a of the member 860 more firmly in place when force is applied to the cover glass 810, thereby improving accuracy of the force-indicating capacitance data.

As stated previously, a gap can be formed between the flexible circuit and the conductive member, as in FIGS. 7, 8. A seal can be placed over the gap to prevent outside moisture from getting in to corrode the components and, in the case of dielectric material in the gap, to prevent the material from leaking out. FIG. 9 illustrates an exemplary sealant element of the sensing device according to various embodiments. In the example of FIG. 9, the open edges of the flexible circuit 940 and the conductive member 960 can be passivated with sealant 980 to seal the openings. In some embodiments, the sealant 980 can also be applied to the solder balls 970 to seal any weak areas. The sealant 960 can be silicone or any other suitable material.

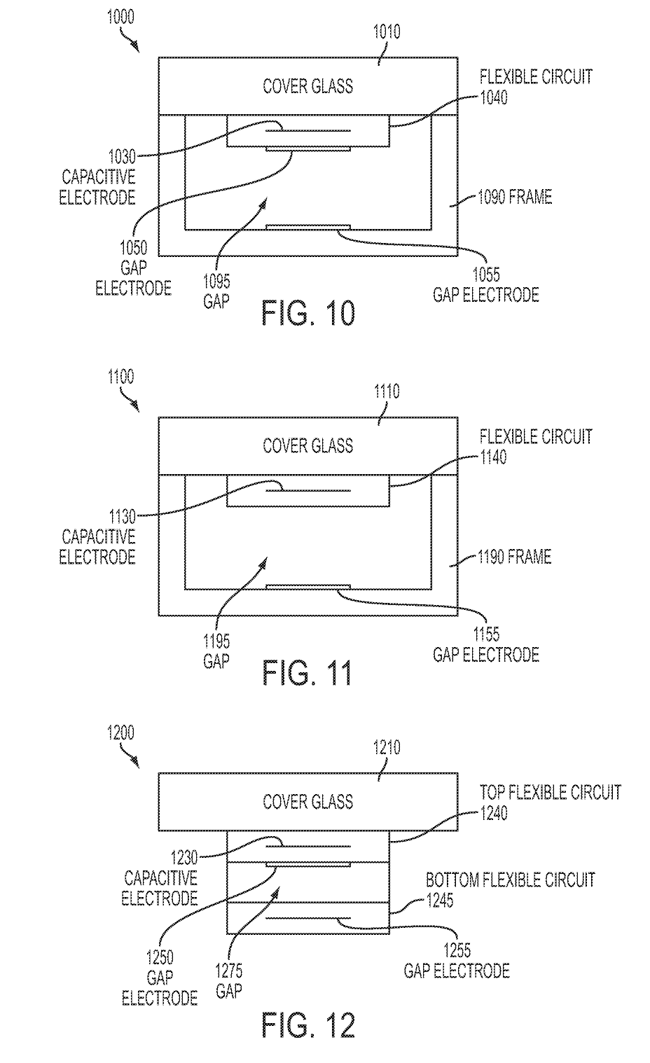

FIG. 10 illustrates an exemplary sensing device having a flexible circuit and a capacitive electrode to provide a force sensor and a proximity sensor according to various embodiments. In the example of FIG. 10, sensing device 1000 can include cover glass 1010, like that of FIG. 1. The device 1000 can also include flexible circuit 1040, having capacitive electrode 1030 embedded therein and gap electrode 1050 disposed thereon, like the flexible circuit of FIG. 7. The device 1000 can further include frame 1090 to seat the cover glass 1010 and to support second gap electrode 1055 that forms the second element of the force sensor (the first element being gap electrode 1050). The second gap electrode 1055 can, in some embodiments, be disposed directly beneath the other gap electrode 1050 and can similarly be a capacitive electrode. Gap 1095 can be formed between the two gap electrodes 1050, 1055.

When force is applied to the cover glass 1010, the cover glass can bow, causing the flexible circuit 1040 to bow as well to close the gap 1095 between the two gap electrodes 1050, 1055, thereby increasing the capacitance therebetween. As the force being applied increases, the gap electrode capacitance can also increase. Thus, when a sensing circuit of the sensing device 1000 detects a rise in capacitance between them, the rise can be interpreted as a force being applied to the cover glass 1010. A baseline capacitance can be established when the gap is at a maximum between the two gap electrodes 1050, 1055 and can be compared to the capacitance when force is applied in order to determine the rise.

Concurrently therewith, the capacitive electrode 1030 can detect the proximity of the object applying the force via a capacitance change in the same manner as the electrode of FIG. 3.

FIG. 11 illustrates another exemplary sensing device having a flexible circuit and a capacitive electrode to provide a force sensor and a proximity sensor according to various embodiments. The sensing device 1100 of FIG. 11 can be the same as the sensing device 1000 of FIG. 10, except single capacitive electrode 1130 of FIG. 11 can replace the capacitive electrode 1020 and the gap electrode 1050 in FIG. 10. Hence, in FIG. 11, the single capacitive electrode 1130 can act as a proximity sensor and as a first element of a force sensor, while second gap electrode 1150 can act as the second element of the force sensor.

When force is applied to the cover glass 1110, the cover glass can bow, causing the flexible circuit 1140 to bow also to close the gap 1195 between the capacitive electrode 1130 and the gap electrode 1155. As a result, the capacitance between the two electrodes 1130, 1155 can increase. As the force being applied increases, the capacitance can correspondingly increase. Thus, when a sensing circuit of the sensing device 1100 detects a rise in capacitance between the two electrodes 1130, 1155, the rise can be interpreted as a force being applied to the cover glass 1110. A baseline capacitance can be established when the gap is at a maximum between the two electrodes 1130, 1155 and can be compared to the capacitance when force is applied in order to determine the rise.

Concurrently therewith, the capacitive electrode 1130 can detect the proximity of the object applying the force via a capacitance change in the same manner as the electrode of FIG. 3.

FIG. 12 illustrates an exemplary sensing device having a double flexible circuit to provide a force sensor and a proximity sensor according to various embodiments. In the example of FIG. 12, sensing device 1200 can have cover glass 1210, like that of FIG. 1. The device 1200 can also have a double flexible circuit disposed on a surface of the cover glass 1210 opposite the touchable surface of the cover glass. The double flexible circuit can have top flexible circuit 1240 and bottom flexible circuit 1245. The top circuit 1240 can have capacitive electrode 1230 embedded therein to form a proximity sensor and first gap electrode 1250 disposed thereon and facing the bottom circuit 1245 to form a first element of a force sensor. The bottom circuit 1245 can have second gap electrode 1255 embedded therein and positioned directly below the first gap electrode 1250 to form the second element of the force sensor. To prevent the bottom circuit 1245 from bowing when force is applied to the device 1200, the bottom circuit can be laminated with a stiffener to make it substantially rigid. The gap electrodes 1250, 1255 can be capacitive electrodes. Gap 1275 can be formed between the top and bottom circuits 1240, 1245. In some embodiments, the gap can be filled with air. In some embodiments, the gap can be filled with a dielectric material.

When force is applied to the cover glass 1210, the cover glass can bow, causing the flexible circuit 1240 to bow also to close the gap 1275 between the two gap electrodes 1250, 1255. This can result in an increase in capacitance between the two electrodes 1250, 1255. As the force being applied increases, the gap capacitance can also increase. Thus, when a sensing circuit of the sensing device 1200 detects a rise in capacitance between the two gap electrodes 1250, 1255, the rise can be interpreted as a force being applied to the cover glass 1210. A baseline capacitance can be established when the gap is at a maximum between the two gap electrodes 1250, 1255 and can be compared to the capacitance when force is applied in order to determine the rise.

Concurrently therewith, the capacitive electrode 1230 can detect the proximity of the object applying the force via a capacitance change in the same manner as the electrode of FIG. 3.

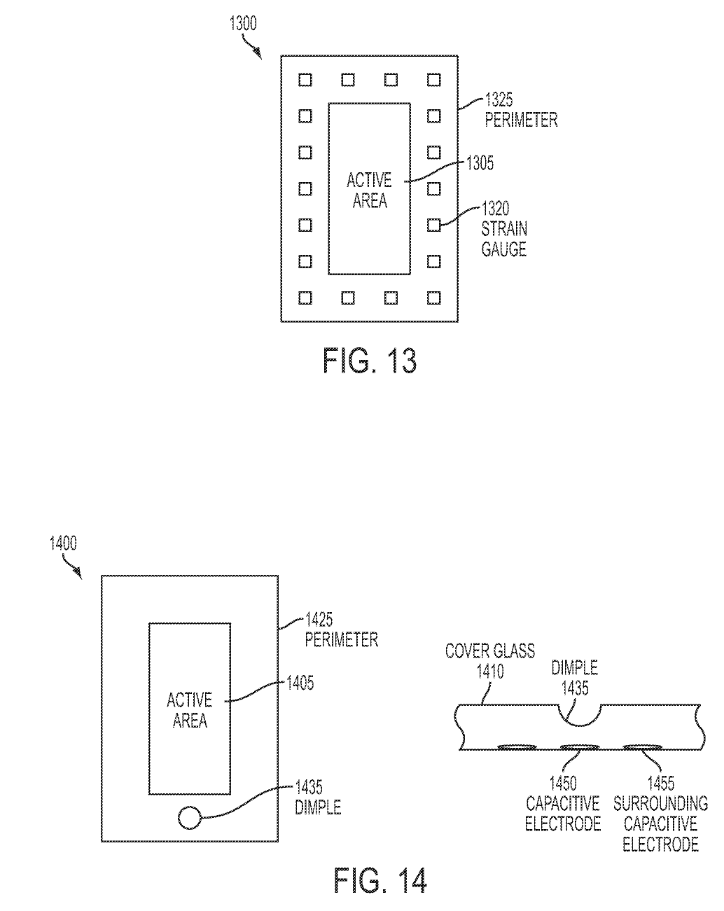

Force can be applied to either a limited area of the sensing device's cover glass, such as at a designated button or dimple, or at multiple areas of the cover glass, depending on the requirements of the device. FIG. 13 illustrates an exemplary display device having multiple force sensors disposed around the device perimeter, where force can be applied to multiple areas of the device. In the example of FIG. 13, display device 1300 can include active area 1205 for displaying graphical data and/or receiving touch inputs in accordance with the displayed data. The device 1300 can also include perimeter 1325 with multiple force sensors 1320 positioned around the perimeter. As such, force can be applied to any one or more areas around the device perimeter 1325 to cause certain actions to occur according to the location(s), the number of locations simultaneously pressed, or the sequence of the locations pressed. In addition, because the sensors 1320 circle the entire perimeter 1325, they can form a grid over the entire display cover glass to detect force applied at any area on the surface, including in the active area 1305.

FIG. 14 illustrates an exemplary display device having a dimple in a surface and capacitive electrodes proximate thereto to provide a combined force and proximity sensor according to various embodiments. In the example of FIG. 14, display device 1400 can include active area 1405 for displaying graphical data and/or receiving touch inputs in accordance with the displayed data. The device 1400 can also include perimeter 1425 with dimple 1435 formed in the device cover glass at a particular perimeter location. The device 1400 can further have multiple capacitive electrodes 1450, 1455 disposed underneath the cover glass, where capacitive electrode 1450 can be directly beneath the dimple 1435 to form a combined force and proximity sensor and capacitive electrodes 1455 can be placed adjacent to and surrounding capacitive electrode 1450 to form additional force sensors.

The capacitive electrode 1450 can detect the seating of an object within the dimple via capacitance change in the same manner as the electrode of FIG. 3. The more seated the object within the dimple 1435, the greater the electrode capacitance decrease. Thus, when a sensing circuit of the sensing device 1400 detects a drop in capacitance of the electrode 1450, the drop can be interpreted as an object being proximate to the dimple 1435. A baseline capacitance can be established when there are no objects proximate to the dimple 1435 and can be compared to the capacitance when the object is seated in the dimple in order to determine the drop.

Concurrently therewith, the capacitance drop measured at the electrode 1450 can be used to detect the force applied by the object to the dimple 1435. Just as the electrode 1450 senses the object, the surrounding electrodes 1455 can also sense the object and have similar capacitance drops. The magnitude of the capacitance drop can be highest at the electrode closest to the object. In this example, the object is in the dimple 1435. As such, the capacitance drop of the electrode 1450 can be higher relative to the capacitance drops of the surrounding electrodes 1455. Thus, when a sensing circuit of the sensing device 1400 detects the capacitance drops, the drop pattern can be interpreted as a force being applied within the dimple 1435. On the other hand, when force is applied at another location, not the dimple, the resultant drop pattern can be interpreted to indicate that other location. This patterning can be advantageously used to detect an accidental press on the device, i.e., a press outside the dimple 1435.

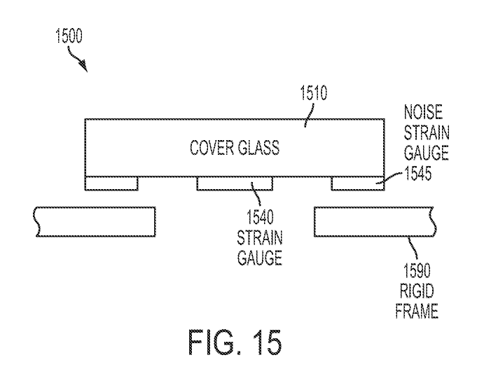

Force and proximity sensors can be susceptible to environmental factors, e.g., temperature changes, and operational factors, e.g., noise, that can affect the ability of the sensors to detect force and proximity. FIG. 15 illustrates an exemplary sensing device that can be used to reduce or eliminate such effects. The sensing device 1500 in FIG. 15 can be the same as the sensing device 600 in FIG. 6, with the addition of strain gauges 1545 to sense the effects of noise on the gauges, such that the noise can be compensated for in the force and proximity measurements made by strain gauge 1540. In the example of FIG. 15, strain gauge 1540 can sense force and proximity in the same manner as the gauge in FIG. 6. To prevent the other strain gauges 1545 from also stretching when the cover glass 1510 bows, rigid frame 1590 can be positioned beneath the gauges to hold them in place. As such, the gauges 1545 can continue to operate as if at rest and provide at-rest resistance data, indicative of device noise. The distance between the gauges can be set so that the noise sensing gauges 1545 are close enough to the force and proximity sensing gauge 1540 to experience the same noise, yet far enough away to avoid stretching when force is applied.

Accordingly, when the strain gauge 1540 detects a force and a proximity and transmits force and proximity measurements to a sensing circuit, the strain gauges 1545 can concurrently transmit their noise measurements to the circuit. The circuit can then apply any appropriate techniques using the two sets of measurements to compensate for noise.

In a similar manner, the strain gauges 1545 can be used to sense the effects of temperature on the gauges, such that the temperature effects can be compensated for in the force and proximity measurements made by strain gauge 1540.

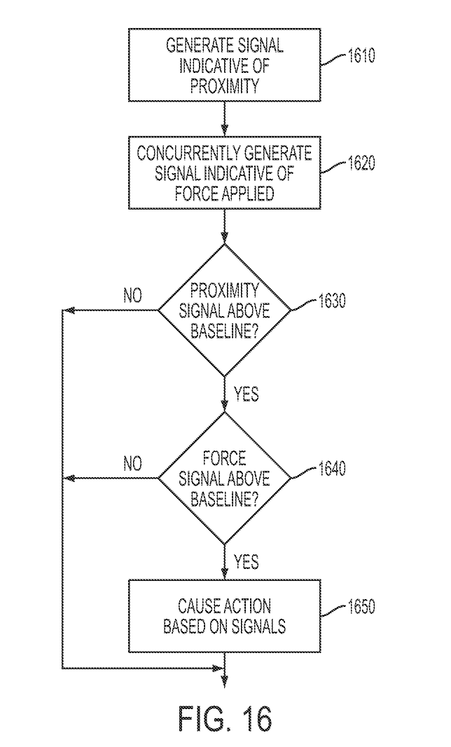

FIG. 16 illustrates an exemplary method for sensing combined force and proximity at a device according to various embodiments. In the example of FIG. 16, a signal indicative of a proximity of an object to the device can be generated (1610). In some embodiments, the signal can be generated by either a resistive sensor or a capacitive sensor via a capacitance change at the sensor. For example, the closer the object is to the device, the greater the capacitance change. Concurrently therewith, a signal indicative of force applied by the object to the device can also be generated (1620). In some embodiments, the signal can be generated by a resistive sensor via a resistance change at the sensor. For example, the object's applied force can cause the device's surface to slightly bow and the underlying resistive sensor to correspondingly deform. The more force applied to the device, the greater the resistance change. In some embodiments, the signal can be generated by a capacitive sensor via a capacitance change at the sensor. For example, the object's applied force can cause the device's surface to slightly bow and the underlying capacitive sensor to correspondingly deform. The more force applied to the device, the greater the capacitance change.

A determination can be made whether the proximity signal measures above a baseline by a first proximity threshold (1630). In some embodiments, the first proximity threshold can be fixed as a percentage of full scale as determined during calibration, e.g., at the factory. If the signal is above the baseline by the first proximity threshold, the signal can be considered true. On the other hand, if the signal is below the baseline by a second proximity threshold, the signal can be deemed false and discarded. In some embodiments, the second proximity threshold can be fixed as a product of the first fixed threshold multiplied by a hysteresis factor. As such, a false proximity signal can be sufficiently different from a true proximity signal so as to avoid cycling between the two because of variation in the object's pressure or position during a touch or hover.

A similar determination can be made whether the force signal measures above a baseline by a first force threshold (1640). If the force signal is above the baseline by the first force threshold, the signal can be considered true. If the signal is below the baseline by a second force threshold, the signal can be deemed false and discarded. In some embodiments, the force thresholds can be fixed to correspond to a given number of grams, as determined during calibration, e.g., at the factory, by using a linear transformation on the force signal.

An action can then be performed by the device based on the true proximity signal and the true force signal (1650).

In some embodiments, the proximity and force baselines can be set at fixed values at the factory or by the user. Alternatively, the baselines can be computed continuously during operation with an adaptive algorithm, for example, which can track slow changes in the proximity and/or force sensors due to temperature, mechanical fatigue, humidity and other drift factors. Here, the baselines can be computed from the sensor signals with a filter having a variable time constant, e.g., an IIR filter, an FIR filter, or some other type of memoryless exponential smoothing filter.

The baselines can be updated with the computed baseline values whenever the sensor signals drop below current baseline values. The variable time constant can be temporarily reset so that the updating can be done quickly, e.g., when a baseline is high upon device wake-up. In some embodiments, the baseline for the proximity sensor can be updated whenever the difference between the proximity signal and the baseline is less than a predetermined threshold. In some embodiments, the predetermined threshold can be computed from a proximity sensor measurement taken when no object is proximate to the sensor. In some embodiments, the baseline for the force sensor can be similarly updated, where its predetermined threshold can be computed from a force sensor measurement taken when no object is applying force.

In some embodiments, the proximity and force signals can be filtered to remove impulsive and random noise using one or more filters, e.g., median filters, running average filters, and the like. This can help reduce sensor and device noise effects and baseline corruption.

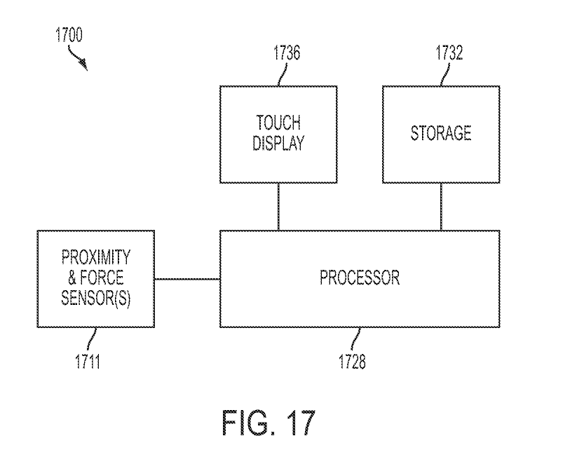

FIG. 17 illustrates an exemplary computing system for sensing combined force and proximity according to various embodiments. In the example of FIG. 17, computing system 1700 can include force and proximity sensor(s) 1711 for sensing a force applied by an object on a surface and a proximity of the object to the surface. The system 1700 can also include processor 1728 for receiving outputs from the sensor(s) 1711 and performing actions based on the outputs that can include, but are not limited to, returning to a home display, waking up a device, moving an object such as a cursor or pointer, scrolling or panning, adjusting control settings, opening a file or document, viewing a menu, making a selection, executing instructions, operating a peripheral device coupled to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. The processor 1728 can also perform additional functions that may not be related to force and proximity sensing, and can be connected to program storage 1732 and touch sensitive display 1736. Display 1736 can include an LCD for providing a user interface to a user of the display and a touch panel for sensing a touch or hover at the display.

Note that one or more of the actions described above, can be performed, for example, by firmware stored in memory or stored in the program storage 1732 and executed by the processor 1728. The firmware can also be stored and/or transported within any non-transitory computer readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “non-transitory computer readable storage medium” can be any medium that can contain or store the program for use by or in connection with the instruction execution system, apparatus, or device. The non-transitory computer readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport readable medium can include, but is not limited to, an electronic, magnetic, optical, electromagnetic or infrared wired or wireless propagation medium.

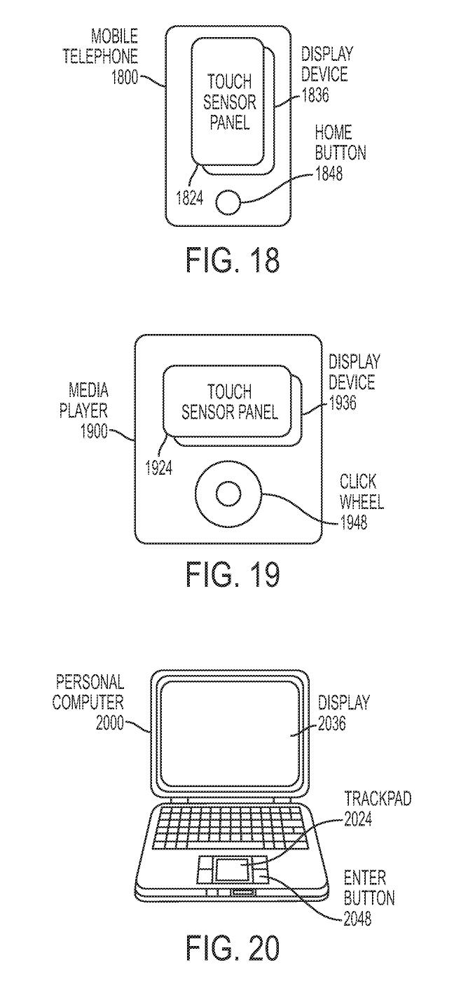

FIG. 18 illustrates an exemplary mobile telephone 1800 that can include home button 1848 having combined force and proximity sensor(s) capable of operating on touch panel 1824, display device 1836, and other computing system blocks according to various embodiments.

FIG. 19 illustrates an exemplary digital media player 1900 that can include clickwheel 1948 having combined force and proximity sensor(s) capable of operating on touch panel 1924, display device 1936, and other computing system blocks according to various embodiments.

FIG. 20 illustrates an exemplary personal computer 2000 that can include enter buttons 2048 having combined force and proximity sensor(s) capable of operating on touch pad 2024, display 2036, and other computing system blocks according to various embodiments.

The mobile telephone, media player, and personal computer of FIGS. 18 through 20 can reduce or eliminate accidental operations thereon using combined force and proximity sensing according to various embodiments.

Although embodiments have been fully described with reference to the accompanying drawings, it is to be noted that various changes and modifications will become apparent to those skilled in the art. Such changes and modifications are to be understood as being included within the scope of the various embodiments as defined by the appended claims.

What is claimed is:

1. A combined force and proximity sensing device comprising:
a first sensor configured to detect a proximity of an object to the device;
a second sensor configured to detect a force applied by the object to the device; and
a flexible circuit including the first sensor therein and proximate to the second sensor,
wherein the first and second sensors detect the respective proximity and force concurrently.

2. The device of claim 1, wherein the first sensor comprises a capacitive sensor and the second sensor comprises a resistive sensor, and wherein the first and second sensors are stacked together.

3. The device of claim 1, wherein the first sensor comprises a capacitive sensor and the second sensor comprises a resistive sensor, and wherein the first and second sensors are positioned side by side.

4. The device of claim 1, wherein a first element of the second sensor is disposed on the flexible circuit, the first sensor comprising a first capacitive electrode and the first element of the second sensor comprising a second capacitive electrode, the device comprising:
a conductive member coupled to the flexible circuit and forming a second element of the second sensor; and
multiple spacers disposed between the flexible circuit and the conductive member to couple the circuit and the member together, forming a gap therebetween.

5. The device of claim 4, wherein the conductive member is rigid.

6. The device of claim 4, wherein the conductive member comprises a rigid portion proximate to the first element of the second sensor and flexible portions coupled to the spacers.

7. The device of claim 4, comprising:
a sealant applied to open edges of the flexible circuit and the conductive member to seal the gap.

8. The device of claim 4, wherein the gap is filled with dielectric material.

9. The device of claim 1, wherein a first element of the second sensor is disposed on the flexible circuit, the first sensor comprising a first capacitive electrode and the first element of the second sensor comprising a second capacitive electrode, the device comprising:
a third capacitive electrode disposed proximate to the first element of the second sensor and forming a second element of the second sensor,
wherein a gap is formed between the first and second elements of the second sensor.

10. The device of claim 1, where a first element of the second sensor is disposed on the flexible circuit, the device comprising:
a second flexible circuit coupled to the flexible circuit and including a second element of the second sensor therein,
wherein the first sensor and the first and second elements are capacitive electrodes and a gap is formed between the flexible circuits.

11. The device of claim 1, wherein the first sensor forms a first element of the second sensor, the device comprising:
a second capacitive electrode disposed proximate to the first sensor and forming a second element of the second sensor,
wherein a gap is formed between the first and second elements of the second sensor.

12. A combined force and proximity sensing device comprising:
a sensor configured to generate a first signal indicative of a proximity of an object to the device and a second signal indicative of a force applied by the object to the device, the sensor generating the first and second signals together.

13. The device of claim 12, wherein the sensor comprises a resistive sensor having multiple traces, the traces configured to lengthen and narrow when the force is applied in order to sense the force and to capacitively couple in order to sense the object proximity.

14. The device of claim 12 incorporated into at least one of a mobile telephone, a digital media player, or a portable computer.

15. An apparatus for combined force and proximity sensing comprising:
a substrate having a touchable surface;
a sensing device proximate to the substrate including
a first sensor configured to generate a first signal indicative of a proximity of an object to the touchable surface, the first sensor disposed within a flexible circuit, and
at least one second sensor configured to concurrently generate a second signal indicative of a force applied by the object to the touchable surface; and
a processor configured to process the first and second signals and to perform an action based thereon.

16. The apparatus of claim 15, comprising:
at least one set of conductive traces selectably coupled to the first and second sensors for transmitting the first and second signals to the processor.

17. An apparatus for combined force and proximity sensing comprising:
a substrate having a touchable surface;
a sensing device proximate to the substrate including a sensor configured to detect together a proximity of an object to the touchable surface and a force applied by the object to the touchable surface; and
a processor configured to process a first signal indicative of the detected proximity and a second signal indicative of the detected force and to perform an action based thereon.

18. The apparatus of claim 17, wherein the sensing device includes a second sensor configured to detect at least one of a temperature effect or a noise at the apparatus, and wherein the processor is configured to compensate at least one of the first signal or the second signal for at least one of the detected temperature effect or the noise.

19. The apparatus of claim 17, wherein the substrate has a dimple in the touchable surface for receiving the object therein, wherein the sensor detects a seating of the object within the dimple and the force applied by the object within the dimple, wherein the sensing device includes multiple sensors surrounding the sensor and proximate to the dimple to detect the force, and wherein the processor is configured to process third signals indicative of the force detected by the multiple sensors and to determine a location relative to the dimple where the force is applied based on the second and third signals.

20. The apparatus of claim 17, wherein the sensing device includes multiple sensors disposed around a perimeter of the substrate to detect the force, and wherein the processor is configured to process third signals indicative of the force detected by the multiple sensors and to determine, based on the second and third signals, the touchable surface location at which the force is applied from among multiple possible touchable surface locations.

21. A method for combined force and proximity sensing at a substantially rigid substrate, the method comprising:
sensing a force applied by an object to a surface of the substrate, the substrate slightly deforming in response to the applied force;
concurrently sensing a proximity of the object to the surface; and
performing an action based on the sensed force and the sensed proximity.

22. The method of claim 21, wherein sensing a force comprises:
deforming a resistive sensor configured to sense the force in association with the deforming of the substrate; and
measuring a change in resistance due to the sensor deformation, the resistance change indicating the force applied.

23. The method of claim 21, wherein sensing a force comprises:
changing a distance between capacitive elements of a sensor configured to sense the force in association with the deforming of the substrate; and
measuring a change in capacitance due to the change in distance, the capacitance change indicating the force applied.

24. The method of claim 21, wherein sensing a proximity comprises:
measuring a change in capacitance of a capacitive sensor configured to sense the proximity, the capacitance change indicating the proximity.

25. The method of claim 21, comprising:
determining whether the sensed force and the sensed proximity exceed corresponding baseline values; and
if so, performing the action, otherwise, skipping the action.
